(19) United States
(12) Patent Application Publication
(10) Pub. No.: US 2010/0231213 A1
(43) Pub. Date: Sep. 16, 2010

(54) MAGNETORESISTIVE SENSOR AS TEMPERATURE SENSOR

(75) Inventors: Jeroen Hans Nieuwenhuis, Eindhoven (NL); Theodorus Petrus Henricus Gerardus Jansen, Eindhoven (NL); Jeroen Veen, Eindhoven (NL); Josephus Arnoldus Henricus Maria Kahlman, Eindhoven (NL); Albert Hendrik Jan Immink, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/294,479

(22) PCT Filed: Mar. 23, 2007
(86) PCT No.: PCT/IB2007/051030

§ 371 Date: Sep. 25, 2008

(30) Foreign Application Priority Data
Mar. 30, 2006 (EP) 06111997.0

(51) Int. Cl. G01R 33/02

(52) U.S. Cl. 324/252

(57) ABSTRACT

A detection system (100, 150) for qualitative or quantitative detection of a magnetic field property of a modulated magnetic field is described. The modulated magnetic field may e.g. stem from an adjacent electrical current (I_{adj}) or magnetic particles. The detection system (100, 150) comprises at least one magneto resistive sensor element (102), a current controller (104) for providing a sensing current (Iₛₑₙₛₑ) flowing through the magnetic sensor element (102) and a controlling means (108). The controlling means (108) is adapted for deriving at a first frequency f₁ a temperature-related parameter of the at least one magneto resistive sensor. The controlling means (108) furthermore is adapted for deriving a qualitative or quantitative characteristic of the adjacent electrical current (I_{adj}) or magnetic particles, taking into account the derived temperature-related parameter. This second frequency (f₁) is different from the first frequency (f₁}). The invention also relates to a corresponding method.

The present invention relates to the field of detectors such as chemical detectors or sensors or biosensors. More particularly, the present invention relates to methods and systems for characterizing magnetic fields, such as e.g. for sensing the presence or determining the amount of magnetic particles and/or current, e.g. for applications in molecular diagnostics using magnetic particles as labels. The present invention also relates to methods and systems for sensing bioactive particles, such as e.g. but not limited to magnetically labeled bioactive particles, using biosensors.

Magneto-resistive sensors, based on e.g. AMR (anisotropic magneto resistance) elements, GMR (giant magneto resistance) elements or TMR (tunnel magneto resistance) elements are nowadays often used in detection systems. Besides the known high speed applications such as magnetic hard disk heads and MRAM, new relatively low bandwidth applications appear in the field of molecular diagnostics, current sensing in IC's, automotive applications, etc. E.g. for molecular diagnostics, biosensors are known that measure the presence of certain biochemical agents based on molecular capture and labeling with magnetic particles. Typically a magneto-resistive sensor measures the magnetic stray field of the bound magnetic particles and the measured magnetic stray field is used for calculating the concentration of agent present. Such sensors typically are aimed at point-of-care applications with a very high sensitivity, i.e. allowing to measure very small concentrations such as concentrations smaller than pico-molar (pM) concentrations.

In several applications, such as in the case of point-of-care applications, exposure to temperature fluctuations of the biosensor may result in a non-stable sensor read-out, leading to erroneous measurements and faulty diagnostics. The latter can be caused by the magneto resistive effect, such as e.g. GMR effect, being function of temperature, meaning that the signal of the biosensor not only changes due to the presence of magnetic markers, but also due to temperature variations. The temperature coefficient of the magneto-resistive effect, e.g. GMR-effect, has been measured to be roughly 2000 ppm, which means that temperature variations of several degrees lead to variations in sensor signal that are relatively large compared to the sensor signal caused by the e.g. magnetic particles. It is typically not possible to differentiate between the signal changes due to temperature variations and the variations as a result of the presence of e.g. magnetic particles.

Theoretically, it would be possible to prevent temperature variations of the sensor by putting it in a temperature-controlled encasing. This is not an attractive solution, since it would be quite costly and it would make the sensor much more bulky, which hamper its suitability for point-of-care applications.

From US 2005/0077890 A1 a dual-purpose magneto-resistive sensor is known, used both for sensing current and for sensing temperature. The document describes a sensor that is multiplexed under separate current conditions to produce both a temperature measurement and a current measurement for a current in the vicinity of the sensor. In order to obtain the temperature measurements and the current measurement, first a resistance is measured for a known first current flowing in a conductor adjacent to the sensor allowing to determine temperature dependency and then measuring a second resistance of the sensor while a second, unknown current is flowing in that conductor adjacent to the sensor allowing to determine a current value of the second unknown current, taking into account the temperature measurements. In order to obtain a time measurement, typically such a sensor requires control of the environment, e.g. the current running through a conductor adjacent to the sensor

In general, in order to enable accurate measurement of low concentrations in samples of bodily fluids, the assay design, the sensor and the sensor signal processing must be sensitive, robust and stable. Temperature variations may disturb an accurate measurement of low concentrations. For example in immunoassays a binding reaction between e.g. an analyte and at least one antibody is involved, which is temperature sensitive. Both the rate of chemical binding reactions and the diffusion of antibodies within the fluid sample are a function of temperature. If the binding dynamics are the basis for analyte concentration measurements, temperature fluctuations during the assay incubation results in systematic errors of the measured target concentrations. Besides reactions of the particles playing a role in the detection, sensors also may show a certain temperature dependency.

It is an object of the present invention to provide efficient and accurate devices and methods for magneto-resistive detection of a magnetic field property of a modulated magnetic field, e.g. the magnitude of a magnetic field. The magnetic field thereby may be any modulated magnetic field. It may for example be generated by magnetic particles or by a current. It is an advantage of embodiments of the present invention that temperature variations can be compensated without the need for numerous additional components, for particular embodiments not used elsewhere in the sensor. It is an advantage of particular embodiments of the present invention that temperature compensated results may be obtained based on a magneto-resistive element having only two terminals. It is also an advantage of particular embodiments of the present invention that temperature insensitivity may be obtained at low cost and for small-sized magneto-resistive sensors.

The above objective is accomplished by a method and device according to the present invention.

The present invention relates to a detection system for qualitative or quantitative detection of a magnetic field property of a modulated magnetic field, the detection system comprising at least one magnetic sensor element, a current controller for providing a sensing current with a first frequency f₁ flowing through the at least one magnetic sensor element and a controlling means, wherein the controlling means is adapted for obtaining an electric characteristic from the at least one magnetic sensor element at a first frequency f₁ for deriving a temperature-related parameter of the at least one magnetic sensor and wherein the controlling means furthermore is adapted for obtaining an electric characteristic from the magnetic sensor element at least a second frequency f₂, the at least a second frequency f₂ being different from the first frequency f₁, for deriving a qualitative or quantitative characteristic of the magnetic field property of a modulated magnetic field taking into account the derived temperature-related parameter.

It is an advantage of embodiments of the present invention that the temperature dependency of the detection system can be taken into account by multiplexing the measurement, while no numerous additional components are needed. With sensing current there is meant the current flowing through the magnetic sensor element and used for obtaining or determining an electrical characteristic of the magnetic sensor.

The magnetic field property of a modulated magnetic may be the magnitude of a magnetic field. The magnetic field may be any modulated magnetic field. The modulated magnetic field may for example be generated by an adjacent electrical current (I_{adj}), magnetic particles also called magnetic beads or any other source. The qualitative or quantitative characteristic may be a presence or amount of adjacent electrical current or magnetic particles. With adjacent electrical current there is meant current flowing in an adjacent conductor in the environment of the detection system.

The magnetic field property of a modulated magnetic field may have a characteristic magnetic field frequency fₘ. The first frequency f₁ may be a frequency substantially different from the magnetic field frequency fₘ and the at least a second frequency f₂ may be at least one of a sum or difference of the magnetic field frequency and the first frequency, i.e. it may equal fₘ+f₁ and/or fₘ−f₁.

It is an advantage of particular embodiments of the present invention that they can be applied to any existing type of detection system based on magnetic sensor elements, such as e.g. magneto-resistive sensor elements or other magnetic sensor elements such as Hall sensor elements.

The detection system furthermore may comprise a modulating means for modulating the magnetic field at the magnetic field frequency fₘ. The modulating means for modulating the magnetic field may be on board, internal or external to the detection system.

The first frequency f₁ may equal 0 hertz.

The controlling means adapted for obtaining an electric characteristic from the magnetic sensor element at a first frequency f₁ and for obtaining an electric characteristic from the magnetic sensor element at a second frequency f₂ may be adapted for obtaining these electric characteristics both at the same time.

The at least one magnetic sensor element may be a Hall sensor or at least one magneto-resistive sensor element. The at least one magneto resistive sensor element may be any of a giant magneto-resistive sensor element, an anisotropic magneto-resistive sensor element or a tunnel magneto-resistive sensor element. It is an advantage of embodiments of the present invention that they the corresponding detection systems may rely on different types of magneto-resistive sensor elements.

It is an advantage of embodiments of the present invention that taking into account the temperature dependence is performed during the use of the detection system, thus taking into account changed conditions for the detection system. In other words, it is an advantage of embodiments of the present invention that taking into account the temperature dependence does not rely on a calibration method performed during manufacturing or initial use of the detection system.

It is an advantage of embodiments of the present invention that temperature dependency can be taken into account for a broad, not necessarily predetermined, range of temperatures.

The present invention also relates to a method for qualitatively and/or quantitatively detection of a magnetic field property of a modulated magnetic field, the method comprising providing a sensing current flowing through at least one magnetic sensor at a first frequency f₁, deriving at the first frequency f₁ a temperature-related parameter of the at least one magnetic sensor, deriving at a second frequency f₂ a qualitative or quantitative characteristic of said magnetic field property of a modulated magnetic field using said at least one magnetic sensor, taking into account the temperature-related parameter of said at least one magnetic sensor.

Deriving the temperature-related parameter may comprise obtaining an electrical characteristic of the at least one magnetic sensor at the first frequency f₁ and determining the temperature-related parameter based on the first electrical characteristic E₁ or a component thereof.

Deriving a qualitative or quantitative characteristic may comprise obtaining a second electrical characteristic of the at least one magnetic sensor at the second frequency and determining the qualitative or quantitative characteristic based on the second electrical characteristic and the temperature-related parameter.

The present invention also relates to the use of a detection system for qualitative and/or quantitative detection of a magnetic field property of a modulated magnetic field for molecular diagnostics, biological sample analysis, or chemical sample analysis, the detection system comprising at least one magnetic sensor element, a current controller for providing a sensing current with a first frequency flowing through the at least one magnetic sensor element and a controlling means, wherein the controlling means is adapted for obtaining an electric characteristic from the magnetic sensor element at a first frequency f₁ for deriving a temperature-related parameter of the at least one magnetic sensor element and wherein the controlling means furthermore is adapted for obtaining an electric characteristic from the at least one magnetic sensor element at least a second frequency f₂, the at least a second frequency f₂ being different from the first frequency f₁, for deriving a magnetic field property of a modulated magnetic field, taking into account the derived temperature-related parameter.

It is also an advantage of particular embodiments of the present invention that both the assay and the detection system, e.g. biosensor or biochip, temperature can be stabilized. In this way, the drift of the binding reaction rate due to temperature variations is reduced and the stability of the detection system, e.g. biosensor or biochip, response is improved.

In a third aspect the present invention also relates to a detection system for qualitative and quantitative detection of bioactive particles, the detection system comprising a particle sensing means for sensing particles or labels thereof, a temperature control means for influencing a temperature of the detection system or part thereof, a temperature sensing means for sensing the temperature of the detection system or part thereof and a controller for controlling the temperature control means based on a temperature related output of the temperature sensing means. The temperature may be a temperature of the particle sensing means or of its environment. The temperature control means may comprise a cooling means for cooling the detection system or part thereof. Such a cooling means may be a Peltier element or a micro-electro-mechanical cooling means. The temperature control means, e.g. the cooling means, the temperature sensing means and the controller may be integrated in the detection system.

Particular and preferred aspects of the invention are set out in the accompanying independent and dependent claims. Features from the dependent claims may be combined with features of the independent claims and with features of other dependent claims as appropriate and not merely as explicitly set out in the claims.

The teachings of the present invention permit the design of improved methods and apparatus for qualitatively or quantitatively determining a magnetic field property of a magnetic field. The magnetic field may be any modulated magnetic field. The modulated magnetic field may for example be generated by an adjacent electrical current (I_{adj}), magnetic particles also called magnetic beads, thus resulting in method suitable for detecting currents or magnetic particles. The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

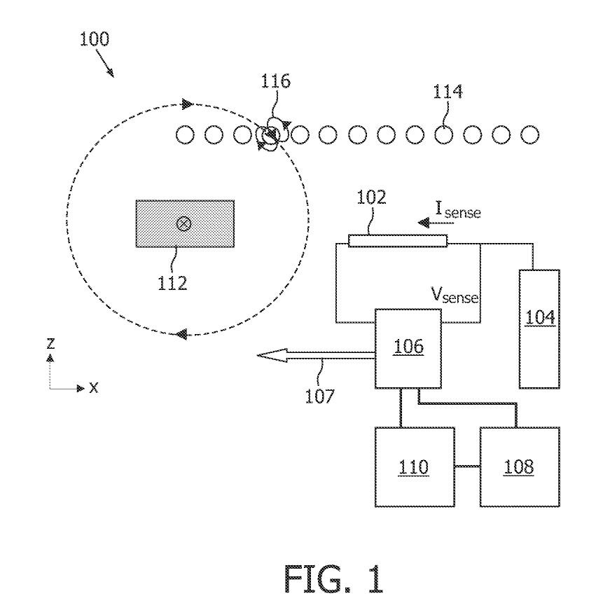

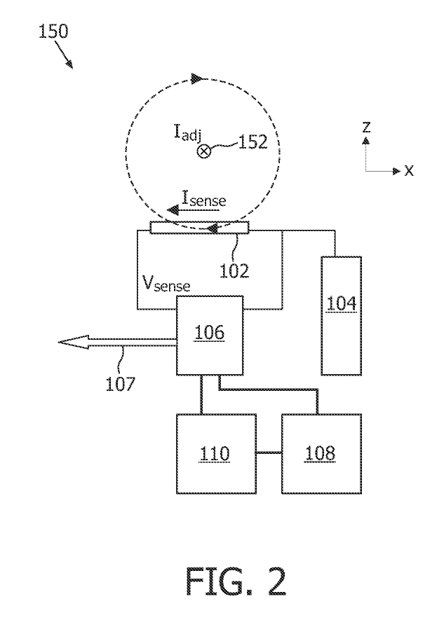

FIG. 1 and FIG. 2 illustrate different exemplary detection systems for temperature independent qualitative or quantitative detection of magnetic particles (FIG. 1) and adjacent current (FIG. 2), according to embodiments of a first aspect of the present invention.

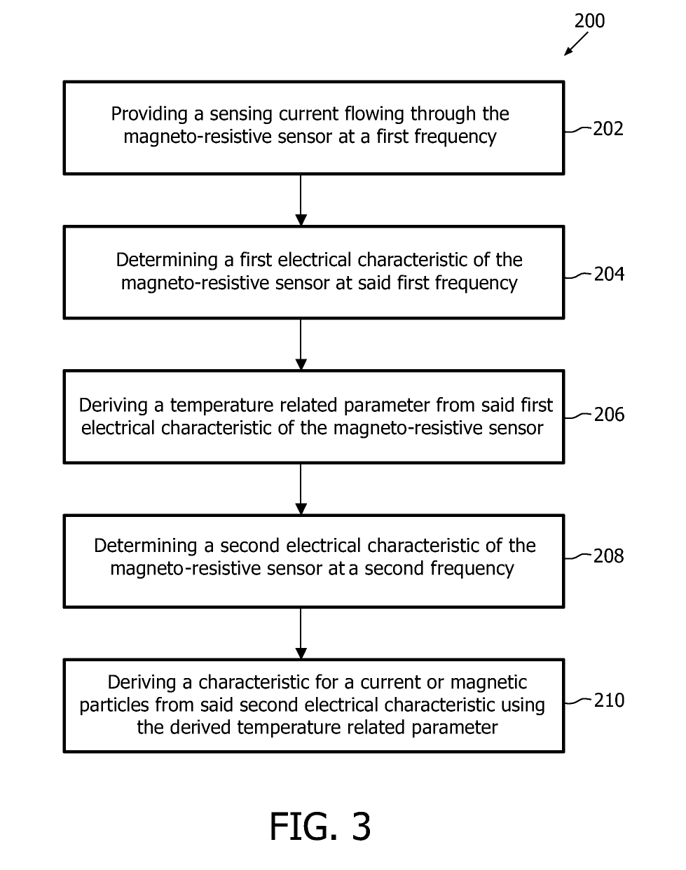

FIG. 3 is a schematic diagram of a method for temperature independent qualitative or quantitative detection of adjacent current or magnetic particles, according to embodiments of a second aspect of the present invention.

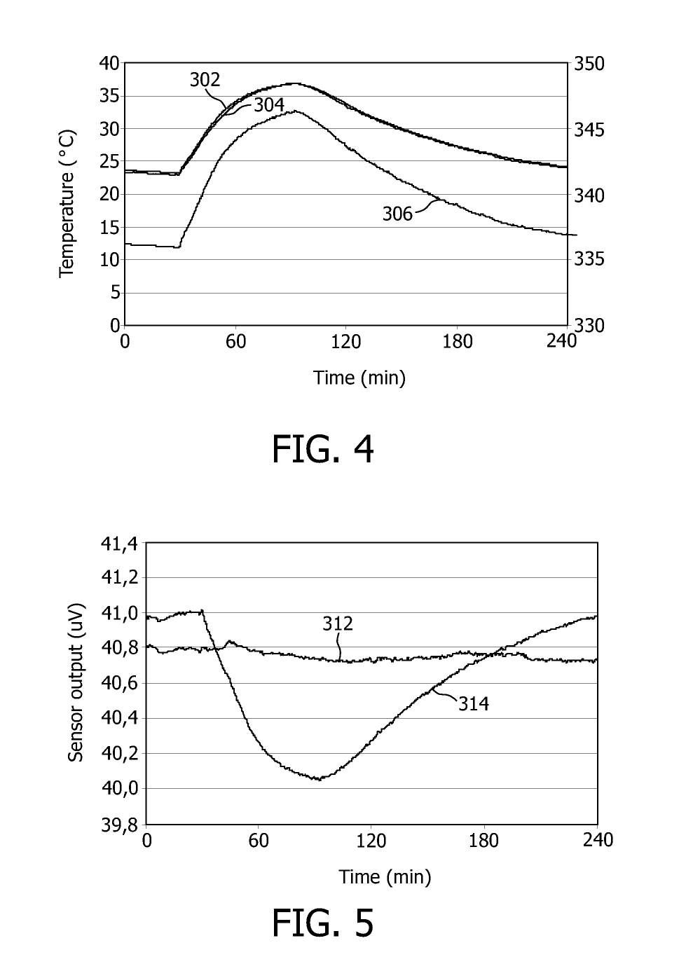

FIG. 4 shows the correlation between the GMR impedance at a first frequency different from the frequency for magnetization, and the GMR-measured and actual temperature, as can be obtained using a sensor according to embodiments according to the present invention.

FIG. 5 illustrates the measurement signal for a temperature compensated and non temperature-compensated sensor output for a temperature behavior as shown in FIG. 4.

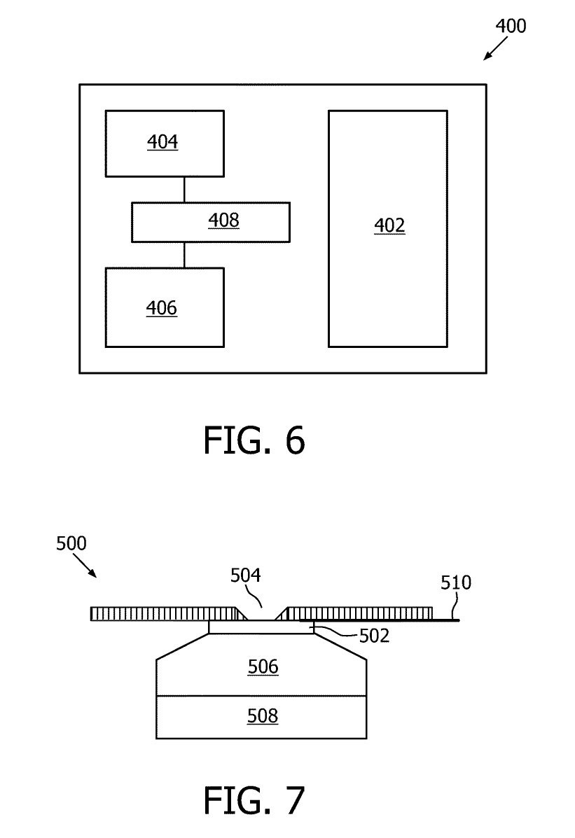

FIG. 6 illustrates a schematic overview of a detection system according to embodiments of the third aspect of the present invention.

FIG. 7 illustrates a detection system with an temperature control means being a Peltier element, according to an embodiment of the third aspect of the present invention.

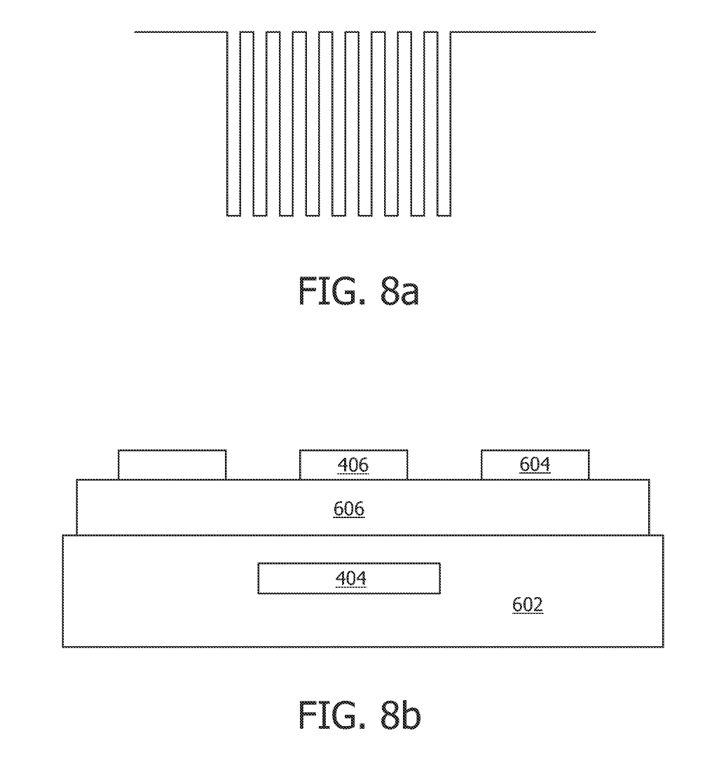

FIG. 8a illustrates a schematic view of a typical Joule heater that may be used in a detection system according to the third aspect of the present invention.

FIG. 8b illustrates a detection system with a temperature control means being a resistive heater, according to an embodiment of the third aspect of the present invention.

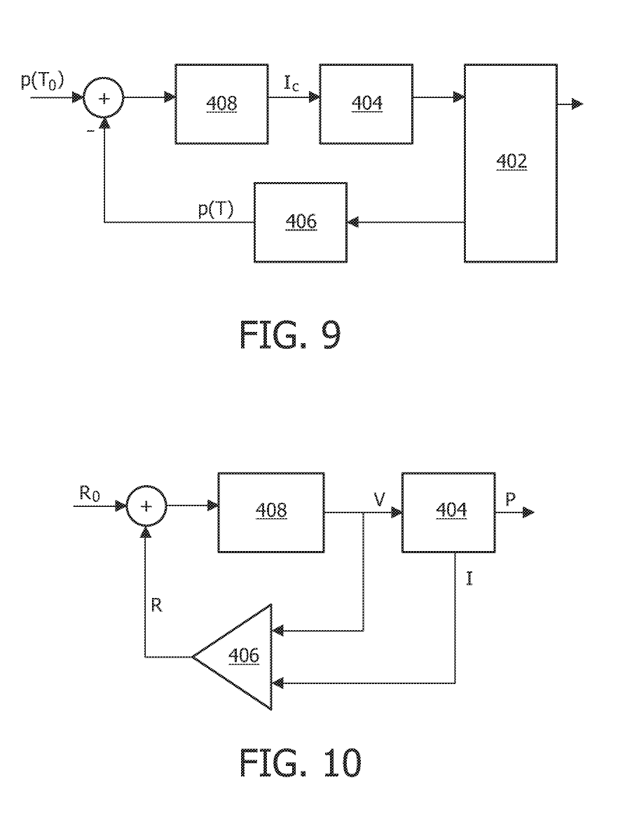

FIG. 9 illustrates a schematic overview of a feedback control system as can be applied for a detection system with a Peltier element, which can be used in a detection system according to embodiments of the third aspect of the present invention.

FIG. 10 illustrates a schematic overview of a feedback control system as can be applied for a detection system with a Joule heater, which can be used in a detection system according to embodiments of the third aspect of the present invention.

In the different figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The following terms or definitions are provided solely to aid in the understanding of the invention. These definitions should not be construed to have a scope less than understood by a person of ordinary skill in the art. A Giant Magneto-Resistive (GMR) sensor element typically comprises a first and a second very thin magnetic film are brought very close together. The first magnetic film is pinned, which means that its magnetic orientation is fixed, usually by holding it in close proximity to an exchange layer, a layer of anti-ferromagnetic material that fixes the first magnetic film's magnetic orientation. The second magnetic film, or sensor film, has a free, variable magnetic orientation. Changes in the magnetic field, in the present case originating from changes in the magnetization of magnetic material, such as superparamagnetic particles, cause a rotation of the sensor film's magnetic orientation, which in turn, increases or decreases resistance of the entire sensor structure. Low resistance occurs when the sensor and pinned films are magnetically oriented in the same direction. Higher resistance occurs when the magnetic orientations of the sensor and pinned films oppose each other. An anisotropic magneto resistance (AMR) sensor element is an element wherein the anisotropic magneto resistance effect occurring in ferro- and ferrimagnetic materials is exploited. It is a change in resistance when a magnetic field is applied which is not parallel to the current flow in a thin strip of ferrous material. The resistance is maximum when the magnetic field applied is perpendicular to the current flow. AMR elements are characterized by high sensitivity, wide operating temperature range, low and stable offset and the wide frequency range, up to units of MHz. Using the proper technological process enables to obtain the linear dependence of the change of resistance on the magnetic field intensity in one specific direction. Tunnel magneto resistance (TMR) sensor elements are sensor elements wherein TMR is exploited, which can be observed in systems made of two ferromagnetic layers separated by an isolating (tunnel) barrier. This barrier must be very thin, i.e., of the order of 1 nm. Only then, electrons can tunnel through this barrier, which is again an entirely quantum-mechanical transport process. The magnetic alignment of one layer can be changed without affecting the other. Changes in the magnetic field, in the present case again originating from changes in the magnetization of magnetic material, such as superparamagnetic particles, cause a rotation of the sensor film's magnetic orientation, which in turn, increases or decreases resistance of the entire sensor structure.

The present invention relates to methods and systems or devices for qualitative and/or quantitative detection of a magnetic field property of a modulated magnetic field, e.g. the presence or magnitude of a magnetic field related to a current, magnetic particles also referred to as magnetic beads or any other source. Typical applications may be in the field of molecular diagnostics, current sensing in IC's, in automotive vehicles, in the automotive industries, etc. By way of illustration, a biosensing process, i.e. in the field of molecular diagnostics, that may be performed using the methods and systems according to embodiments of the present invention, will be first described below. In biosensing processes using a magnetic detection system, typically magnetic particles, also referred to as magnetic beads, may be directly or indirectly attached to target molecules such as e.g. proteins, antibodies, nucleic acids (e.g. DNR, RNA), peptides, oligo- or polysaccharides or sugars, small molecules, hormones, drugs, metabolites, cells or cell fractions, tissue fractions, etc. These molecules are to be detected in a fluid, which can be the original sample or can already have been processed before insertion into the biosensor (e.g. diluted, digested, degraded, biochemically modified, filtered, dissolved into a buffer). The original fluids can be for example, biological fluids, such as saliva, sputum, blood, blood plasma, interstitial fluid or urine, or other fluids such as drinking fluids, environmental fluids, or a fluid that results from sample pre-treatment. The fluid can for example comprise elements of solid sample material, e.g. from biopsies, stool, food, feed, environmental samples. The surface of the detection system may be modified by attaching molecules to it, which are suitable to bind the target molecules which are present in the fluid. The surface of the sensor can also be provided with organisms (e.g. viruses or cells) or fractions of organisms (e.g. tissue fractions, cell fractions, external and internal membranes or membrane fragments). The surface of biological binding can be in direct contact with the sensor chip, but there can also be a gap between the binding surface and the sensor chip. For example, the binding surface can be a material that is separated from the chip, e.g. a porous material. Such a material can be a lateral-flow or a flow-through material, e.g. consisting of microchannels in silicon, glass, plastic, etc. Before the magnetic particles or the target molecules/magnetic particles-combination can be bound to the surface of the detection system, they have to be attracted towards that surface. The present invention provides methods and systems for improving the accuracy of detection by taking into account environmental temperature effects in the detection result.

Whereas examples and illustrations for the following embodiments will be related to the use of a giant magneto-resistive (GMR) element, the present invention is not limited thereto but is more generally related to the use of a magnetic sensor element. For example, AMR (anisotropic magneto resistance) elements or TMR (tunnel magneto resistance) elements also may be used, as well as e.g. a Hall sensor element.

In a first aspect, the present invention relates to a detection system for qualitatively and/or quantitatively detecting a magnetic field property of a modulated magnetic field, e.g. the presence or magnitude of a modulated magnetic field. The magnetic field may for example be generated by an adjacent current, magnetic particles in the environment of the detection system, or any other source. The magnetic field property typically is characterized by a magnetic field frequency fₘ. This frequency typically corresponds with the modulation frequency of the magnetic field studied. It may for example be the magnetic field frequency fₘ of the magnetic field generated by magnetic particles or the magnetic field frequency fₘ of the magnetic field generated by the adjacent current I_{adj}. The detection system thereby is adapted to compensate for the effects of temperature variations. A schematic overview of exemplary detection systems 100, 150 according to embodiments of the first aspect are shown in FIG. 1 and FIG. 2. The detection system 100, 150 comprises at least one magnetic sensor element 102, such as e.g. a Hall sensor element or a magneto-resistive sensor element such as for example a GMR sensor element, or a TMR sensor element or an AMR sensor element. The at least one magnetic sensor element may be a single magnetic sensor element but also may be a plurality of magnetic sensor elements, e.g. an array of magnetic sensor elements. Typically, detection of a magnetic field property of a modulated magnetic field such as the presence or magnitude of a modulated magnetic field, e.g. generated by a current I_{adj} flowing in the environment of the at least one magnetic sensor element, generated by magnetic particles present in the environment of the at least one magnetic sensor element or generated by any other means is performed by measuring and evaluating an electrical characteristic of the at least one magnetic sensor element 102, such as e.g. an impedance. Measurement of such an electrical characteristic may e.g. be performed by forcing a sensing current Iₛₑₙₛₑ through the sensor and measuring voltage Vₛₑₙₛₑ over the sensor. Typically, in order to perform such a measurement, the detection system 100, 150 comprises a current controller 104 for providing such a sensing current Iₛₑₙₛₑ having a first frequency f₁ and flowing through the at least one magnetic sensor element 102. The current controller 104 for providing a sensing current Iₛₑₙₛₑ may for example be a current source or a voltage source. The sensor furthermore may comprise determination means 106 for determining a voltage and deriving thereof a magnetic property of a modulated magnetic field. The determination means 106 furthermore may be adapted for deriving from the magnetic field property of the modulated magnetic field for example a qualitative or quantitative characteristic of a current I_{adj} to be measured or of magnetic particles present. The determination means 106 typically may comprise means for determining an electrical characteristic and processing capacity for determining from the electrical characteristic the magnetic field property of the modulated magnetic field. Furthermore the processing capacity may allow determining a qualitative or quantitative characteristic of the adjacent current or magnetic particles to be detected. Such a processing capacity may be provided by a processor. Determining from the electrical characteristic a qualitative or quantitative magnetic field property may be e.g. performed using an algorithm or a look-up table. The determination means 106 furthermore may comprise an output means 107 for outputting a result for the qualitative or quantitative magnetic field property or other parameters derived therefrom.

According to the first aspect of the present invention, the detection system 100, 150 comprises a controlling means 108 for controlling obtaining electrical characteristics of the magnetic sensor element 102 at different frequencies. By obtaining electrical characteristics at different frequencies, both temperature characteristics and characteristics of the magnetic field, e.g. generated by an adjacent current I_{adj}/magnetic particles, can be determined. The controlling means may be adapted for controlling obtaining the electrical characteristics of the magnetic sensor elements 102 at different frequencies subsequently or at the same time. Measurement of a first electrical characteristic E₁ of the at least one magnetic sensor element 102 at the first frequency of the sensing current Iₛₑₙₛₑ typically results in a first electrical characteristic E₁ that is independent of the magnetic field, e.g. generated by an adjacent current I_{adj} or of the number of magnetic particles present in the environment of the at least one magnetic sensor element 102. This electrical characteristic E₁ allows determination of a temperature-related parameter of the magnetic sensor element 102 or its environment. Measurement of a second electrical characteristic E₂ of the at least one magnetic sensor element 102 at a second frequency allows to obtain a second electrical characteristic E₂ that is dependent on the magnetic field, e.g. adjacent current or the number of magnetic particles present in the environment of the at least one magnetic element. Thereby the temperature related parameter obtained based on the first electrical characteristic E₁ typically is taken into account. It is to be noted that, in particular embodiments, the first frequency (f₁) may equal 0 hertz. Nevertheless, it is preferred that the first frequency f₁ is not zero, as modulated signals typically can be measured with a better signal to noise ratio than DC signals. Using modulated signals may allow for example a very accurate read out of the electrical characteristic using filtering techniques.

In other words, the controlling means 108 thus is adapted for determining an electrical characteristic of the magnetic sensor element 102 at a first frequency f₁, different from the magnetic field frequency fₘ, allowing to derive at this frequency f₁ a first electrical characteristic E₁ or a component thereof that is temperature dependent and that is independent of the magnetic field, e.g. generated by adjacent current I_{adj} or by a number of magnetic particles present. The electrical characteristic E₁ or a component thereof obtained at the first frequency f₁ thus is a function of temperature T but is not dependent on the magnetic field, e.g. generated by adjacent current or magnetic particles present in the environment of the at least one magnetic sensor element 102, i.e.

E₁=E(f₁, T, but not dependent upon magnetic field) [1]

Consequently it allows to determine a temperature-related parameter for the magnetic sensor element or its environment. Such a temperature-related parameter may be the temperature of the at least one magnetic sensor element 102, the temperature of its environment or any other parameter indicative of a temperature of the at least one magnetic sensor element 102 or its environment.

The controlling means 108 also is adapted for determining an electrical characteristic of the magnetic sensor element 102 at a second frequency f₂, different from the first frequency f₁, such that a second electrical characteristic E₂ of the magnetic sensor can be derived at this frequency f₂. The second electrical characteristic E₂ thereby is dependent on the magnetic field, e.g. generated by a number of magnetic particles, by an amount of current or by any other source. The electrical characteristic E₂ obtained at the second frequency f₂ thus is a function of temperature T but is also dependent on the magnetic field, e.g. generated by adjacent current or magnetic particles present in the environment of the at least one magnetic sensor element 102, i.e.

E₂=E(f₂, T, magnetic field) [2]

The second frequency f₂ preferably equals fₙ, and/or fₘ+f₁. By using a temperature-related parameter of the at least one magnetic sensor element 102 derived using the sensing current Iₛₑₙₛₑ at the first frequency f₁, the temperature dependency of the second electrical characteristic E₂ measured at the second frequency f₂ can be taken into account. The latter allows to derive from the second electrical characteristic E₂ a qualitative or quantitative magnetic field property of a magnetic field, e.g. generated by adjacent current or magnetic particles present in the environment of the at least one magnetic sensor element, which is temperature independent. In this way more accurate results, being independent of the environmental temperature, can be obtained. In conclusion, the controlling means 108 thus is adapted for controlling the determining means 106 for deriving electrical characteristics at the selected frequencies. The controlling means 108 therefore may provide controlling signals to the determining means 106. Whereas the controlling means 108 in the present examples is shown as a single part, it may be split up in different parts.

In order to derive the temperature dependency of the at least one magnetic sensor element 102, the detection system 100, 150 preferably comprises a processing means 110 for deriving from the first electrical characteristic a temperature-related parameter indicative of a temperature of the at least one magnetic sensor element 102 or of its environment. Such a processing means 110 may be a separate processing means or may use processing capacity of the determination means 106. The processing means 110 may be a dedicated circuitry such as e.g. a microcomputer, a digital signal processor (DSP), a general purpose processor, an application specific integrated circuit (ASIC), a microprocessor, etc. It may be adapted for determining the temperature-related parameter e.g. using an algorithm or a look-up table or in any other suitable way.

The detection system 100, 150 according to the present invention thus is adapted for qualitative or quantitative detection of a magnetic field property or a magnetic field, e.g. generated by adjacent current I_{adj} and/or magnetic particles present in the environment of the at least one magnetic sensor element in a temperature independent way. From the magnetic field property, a qualitative or quantitative property of the source generating the magnetic field, e.g. of an adjacent current and/or magnetic particles present in the environment may be determined. Qualitative or quantitative detection may for example be detection of the presence or the amount of adjacent current I_{adj} or magnetic particles. If e.g. magnetic particles are to be detected, as shown in more detail in FIG. 1, the detection system 100, 150 typically may comprise at least one modulating means 112 modulating the magnetic field. The modulating means 112 may be an on-chip magnetic field generating means, such as e.g. a current wire, or it may be an external magnetic field generating means. The modulating means 112 may for example be a modulating means such as a current wire, an electromagnet or external coils. Magnetic particles 114 in the magnetic field develop a magnetic moment thus generating dipolar stray fields 116 having in-plane magnetic field components lying in plane with the plane of the at least one magnetic sensor element 102. As these influence the at least one magnetic sensor element 102, the latter allows detection of such magnetic particles 114. The presence of a modulating means 112 thus allows detection of magnetic particles 114 using the magnetic sensor element 102. Typically, the modulating means 112 may be oriented such that the resulting magnetic field generated for magnetizing magnetic particles is oriented to a relatively insensitive direction of the magnetic sensor, e.g. the direction perpendicular to the plane of the magnetic sensor which is the z-direction in FIG. 1. In this way, the magnetic field generated by the modulating means 112 does not influence the measurement by the magnetic sensor too much.

Another example is detection of an adjacent current I_{adj} flowing through a conductor adjacent 152 to the at least one magnetic sensor 102 element. If adjacent current I_{adj} flows through an adjacent conductor 152, this typically results in the generation of a magnetic field. If the orientation of the at least one magnetic sensor element 102 and the adjacent conductor 152 is selected appropriate, the generated magnetic field may have a substantial in-plane component, resulting in the influencing of the at least one magnetic sensor element 102, thus allowing to measure the presence or the amount of current flowing through the adjacent conductor 152. An illustration thereof is shown in FIG. 2.

Further components or features, e.g. for the reduction of noise, may also be provided in the detection system without leaving the scope of the present invention.

The obtained temperature information also may be used for controlling the temperature of the detection system. It may be used for controlling a heating and/or cooling means for controlling the temperature of the detection system.

In a second aspect, the present invention relates to a method for qualitatively and quantitatively detecting a magnetic field property of a magnetic field, e.g. generated by an adjacent current I_{adj} or magnetic particles. The method thereby comprises providing a sensing current Iₛₑₙₛₑ modulated at a first frequency and deriving at the first frequency a temperature related parameter of the at least one magnetic sensor element 102, the temperature-related parameter being indicative of a temperature T of the at least one magnetic sensor element 102 or its environment. It furthermore comprises deriving, at a second frequency f₂, a characteristic for said magnetic field property of a magnetic field, e.g. generated by adjacent current I_{adj} or magnetic particles, can be derived, taking into account said temperature related parameter.

By way of example, basic and optional steps of an exemplary method 200 for qualitatively and/or quantitatively detecting a magnetic field property of a magnetic field, e.g. generated by adjacent current or magnetic particles, according to the second aspect are shown in FIG. 3. The method is especially suitable when using a detection system 100, 150 as described in the first aspect according to the present invention.

A first step 202 comprises providing a sensing current Iₛₑₙₛₑ flowing through at least one magnetic sensor element 102 at a first frequency f₁. This first frequency f₁ typically differs from the magnetic field frequency fₘ of a magnetic field for which a magnetic field property is to be detected. Depending on how the magnetic field is generated, prior to step 202, the additional steps of providing a magnetic field for magnetizing magnetic particles to be detected may be performed and/or bringing the detection system in proximity to a conductor for which the present or the amount of current flowing through may be performed. These steps are not shown in FIG. 3 and may be but are not necessary part of the method 200. Using a first frequency f₁ different from the magnetic field frequency fₘ shall allow to obtain a temperature-related parameter for the at least one magnetic sensor 102.

A second step 204 comprises determining, at the first frequency f₁, a first electrical characteristic E₁ of the at least one magnetic sensor element 102 for the sensing current Iₛₑₙₛₑ flowing through the at least one magnetic sensor element 102. Such an electrical characteristic E₁ may be e.g. an impedance of the at least one magnetic sensor element 102, although the invention is not limited thereto. Determining a first electrical characteristic E₁ at the first frequency f₁ may be performed by determining a voltage over the at least one magnetic sensor element 102, allowing to determine the impedance as the sensing current Iₛₑₙₛₑ flowing through the at least one magnetic sensor element 102 is known. Detecting the electrical characteristic E₁ at frequency f₁, different from the magnetic field frequency fₘ, as described in step 202 results in a detected characteristic that does not depend on the magnetic field, e.g. generated by a number of particles or adjacent current flowing in an adjacent conductor in the environment of the at least one magnetic sensor 102.

In a third step 206, a temperature related parameter is derived from the first electrical characteristic E₁ of the at least one magnetic sensor element 102. Such a temperature-related parameter may be obtained using a standard algorithm, by using look-up tables (LUT) or based on a reference results correlating the electrical characteristic with the temperature-related parameter in any suitable way. The temperature-related parameter may be a temperature of the at least one magnetic sensor element, an environmental temperature of the at least one magnetic sensor element, or any other type of parameter related to temperature.

In a fourth step 208, a second electrical characteristic E₂ of the magnetic sensor element is determined at a second frequency f₂, different from the first frequency f₁, whereby the frequency f₂ is such that it allows to obtain a qualitative or quantitative characteristic for a magnetic field property of a magnetic field, e.g. generated by the current present in an adjacent conductor or by the magnetic particles present in the environment. The frequency preferably may equal the difference and or the sum of the magnetic field frequency fₘ of the magnetic field for which the magnetic field property is to be determined and the first frequency, i.e. fₘ−f₁ or fₘ+f₁. At this frequency, the second electrical characteristic E₂ comprises components that are dependent on the magnetic field, e.g. generated by adjacent current present in an adjacent conductor and/or magnetic particles present in the environment.

In a fifth step 210, a qualitative or quantitative characteristic parameter for a magnetic field property of a magnetic field, is derived from the second electrical characteristic E₂, thereby taking into account the derived temperature-related parameter. The latter may be performed using a predetermined algorithm, using look-up tables (LUT) or in any other suitable way. Taking into account temperature-related information for the measurement allows to obtain a detection method with increased accuracy.

It is to be noted that although the steps are shown as subsequent in the exemplary method of FIG. 3, deriving the electrical characteristics at different frequencies as performed in steps 204 and 208 may be performed simultaneously, whereby after determining the electrical characteristics at different frequencies the temperature related parameter may be calculated from the first electrical characteristic and the qualitative and/or quantitative characteristic of the magnetic field property may be determined subsequently, taking into account the temperature related parameter.

It furthermore is to be noticed that, in particular embodiments, the first frequency (f₁) may equal 0 hertz. Nevertheless, it is preferred that the first frequency f₁ is not zero, as modulated signals typically can be measured with a better signal to noise ratio. The latter may allow very accurate read out of the electrical characteristic using filtering techniques.

Without being limited by theory and by way of example, the electrical behavior of magnetic sensor elements for systems and/or methods as described in the first and second aspect of the present invention is discussed below. By way of illustration, the latter is discussed for a giant magneto-resistive sensor element, the invention not being limited thereto. A giant magneto-resistive sensor element typically is a resistor that changes its impedance as a function of magnetic field strength H. Both the GMR-coefficient G(H) and the GMR-resistance R_{GMR} itself are a function of temperature T. The latter is illustrated in equation [3],

R_{GMR}=R₀[1+α(T−T₀)+G(H)(1+β(T−T₀))] [3]

where α is the temperature coefficient of the GMR-sensor, β is the temperature coefficient of the GMR-effect, T is the actual temperature and T₀ is the initial temperature at which the initial resistance R₀ is obtained. The sensor typically is read-out by forcing a sensing current I_{GMR} through the sensor and measuring the voltage over the sensor.

If it is assumed that the magnetic particles, also referred to as magnetic beads, are magnetized at a magnetic field frequency fₘ, the magnetic field strength H can be expressed as

H=H₀ cos(2πfₘt) [4]

with H₀ the maximum magnetic field strength. According to the present invention, the sensing current flowing through the GMR-sensor is modulated at a first frequency f₁. This frequency typically is different from magnetic field frequency fₘ. The sensing current I then can be expressed as

I=I₀ cos(2πf₂t) [5]

For such a sensing current, flowing through the GMR sensor, the voltage that can be measured over the GMR sensor is given by equation [6],

V_{GMR}=IR_{GMR}=I(f₁)·R₀[1+α(T−T₀)+G(H(fₘ))(1+β(T−T₀))] [6]

It can be seen that the GMR voltage has two different components, i.e. one component V_{independent}_{_{—}}_{of}_{_{—}}_{magnetic}_{_{—}}_{particles} that does not depend on the number of magnetic particles, also referred to as magnetic beads, and one component V_{independent}_{_{—}}_{of}_{_{—}}_{magnetic}_{_{—}}_{particles} that does depend on the number of magnetic particles. The component V_{independent}_{_{—}}_{of}_{_{—}}_{magnetic}_{_{—}}_{particles} that does not depend on the number of magnetic particles is given by equation [7], i.e.

V_{independent}_{_{—}}_{of}_{_{—}}_{beads}=I(f₁)R₀(1+α(T))=I₀R₀(1+α(T))cos(2πf₁t) [7]

This component is characterized by a frequency f₁. If the voltage over the GMR sensor is measured at this frequency f₁, the temperature fluctuations can be measured without being influenced by the presence of magnetic particles. So by measuring the voltage signal at frequency f₁ the GMR sensor can be used as a temperature sensor.

Voltage components V_{independent}_{_{—}}_{of}_{_{—}}_{magnetic}_{_{—}}_{particles} that depend on the number of magnetic particles can be found at the frequencies fₘ−f₁ and fₘ−f₁:

$$\begin{matrix}{V}_{beads} ( T - {T}_{0} ) = I ( {f}_{1} ) {R}_{0} G ( H ( {f}_{m} ) ) ( 1 + β ( T - {T}_{0} ) ) \\ = {I}_{0} {R}_{0} {G}_{0} {H}_{0} ( 1 + β ( T - {T}_{0} ) ) \\ cos ( 2 π {f}_{1} t ) cos ( 2 π {f}_{m} t ) \\ = \frac{1}{2} {I}_{0} {R}_{0} {G}_{0} {H}_{0} ( 1 + β ( T - {T}_{0} ) ) \\ ( cos ( 2 π ( {f}_{m} - {f}_{1} ) ) + cos ( 2 π ( {f}_{m} + {f}_{1} ) ) )\end{matrix} \qquad [ 8 ]$$

These signal components depend on the magnetic field created by the magnetic particles (H₀) and on temperature. Such components thus can be obtained by determining the voltage signal at frequency f₂, equal to (fₘ−f₁) or (fₘ+f₁). The temperature dependency can be compensated for using the temperature information, i.e. a temperature-related parameter such as e.g. the temperature T itself, obtained at frequency f₁. As a consequence a signal can be obtained that solely depends on the number of magnetic particles, or in other words that is temperature independent. Similar results and equations can be obtained for a anisotropic magneto-resistive sensor element or a tunnel magneto-resistive sensor element or another magnetic sensor element such as a Hall sensor element.

The methods and systems as described in the first and second aspect according to the present invention will be further illustrated by experimental results. An example of a temperature compensated magnetic particles detection is shown with reference to FIG. 4 and FIG. 5. In the present example, the sensor is exposed to a temperature variation of about 15° C. The sensor used comprises a giant magneto-resistive sensor element. First a temperature-related parameter, in the present case the temperature itself, was determined, based on measurement at frequency f₁. The results thereof are shown in FIG. 4, illustrating both the temperature derived from the measurement at frequency f₁ and a temperature measured with a conventional external temperature sensor. It can be seen that the calculated temperature 302, derived according to a method of the present invention, matches very well with the actual temperature 304, measured with a conventional external temperature sensor. FIG. 4 furthermore indicates the impedance signal 306 of the GMR sensor element at frequency f₁, indicating a close correlation between the impedance signal 306 and the actual temperature 304. The latter also indicates that this signal can be used for temperature sensing. Based on the impedance signal 306 measured at the first frequency f₁, a corrected sensor signal can be obtained, i.e. a sensor signal corrected for temperature variations. The latter is illustrated in FIG. 4, where both the T-corrected sensor output 312 and the non-T-corrected sensor output 314 are shown. It can be seen that the variations due to the temperature sensitivity of the sensor could be fully compensated. The remaining drift term is due to drift in the read-out electronics. The present example illustrates how, using methods and devices according to the present invention, a biosensor detection can be made robust against temperature fluctuations, based on frequency multiplexing.

It is an advantage of embodiments according to the present invention that the magneto-resistive element of the biosensor can be used to record both magnetic field strength and temperature fluctuations at the same time. The temperature information may be used to compensate the magnetic measurements for temperature dependence.

The methods and systems according to the present invention fit in with the default operation method and default operation equipment of a bio sensor. Typically biosensors are already based on frequency multiplexing, thus allowing to use frequency multiplexing for temperature measurements as soon as a controlling means is available for controlling such a frequency multiplexing. The method for performing temperature compensation thus does not require additional components, but only the adaptation of the controlling means and possibly additional processing means. The methods and systems of the present invention therefore are easy to implement to existing systems.

In a third aspect, the present invention also relates to methods and systems or devices for qualitative and/or quantitative detection of chemical or biological entities, e.g. bioactive particles, which are subject to variations of temperature. Typical examples of applications for such detection systems include sandwich and competitive immunoassays for analyte concentration measurements using labeled antibodies. According to this third aspect, the methods and systems or devices may be related to magneto-resistive sensors, although the invention is not limited thereto. For example, methods and systems or devices of the present invention also may relate to detection based on fluorescent labels. By way of illustration, an example biosensing process as can be performed according to the methods and systems of the third aspect of the present invention is described in more detail above, comprising similar features and advantages. It nevertheless is to be noted that the invention is not limited thereto.

It is an advantage of embodiments according to the third aspect of the present invention that methods and systems for qualitative and/or quantitative detection of bioactive particles are obtained wherein the drift of the binding reaction rate due to temperature variations is reduced and the stability of the biosensor response is improved. It is also an advantage of embodiments according to the third aspect of the present invention that the drift of the electrical response of the detection system, i.e. biochip or biosensor, to e.g. magnetic labels, is reduced.

In a first embodiment according to the third aspect of the present invention, a system for qualitative and/or quantitative detection of bioactive particles is provided. The detection system 400, schematically shown in FIG. 6, typically is adapted for detecting bioactive particles and therefore comprises a particle sensing means 402 for sensing bioactive particles, a temperature control means 404 for controlling the temperature, a temperature sensing means 406 for determining the temperature and a controller 408 for controlling the temperature control means 404 in view of the temperature determined with the temperature sensing means 406. The latter allows temperature stabilization by active control using the temperature control means 404. In particular embodiments the detection system may involve a re-usable reader system and a disposable unit in which the sample is entered. The disposable unit thereby typically is adapted to be read out by the re-usable reader system. Different components of the detection system may be part of the re-usable reader device or may be part of the disposable cartridge. If the different components of the detection system are integrated in the re-usable reader device, the disposable cartridge does not need to be part of the invention.

The different components of the detection system 400 will now be discussed in more detail. The particle sensing means 402 may be any suitable sensing means. If e.g. the detection system is based on detection of magnetic labeled bioactive particles, the particle sensing means 402 may be a magnetic sensor, such as e.g. but not limited to a Hall sensor or a magneto-resistive sensor, such as a giant magnetoresistive sensor, an anisotropic magneto resistance or a tunnel magneto resistive sensor. If the detection system is based on detection of luminescent labeled bioactive particles, the particle sensing means 402 may be a luminescence detector and may furthermore comprise an excitation source, if the labels need to be excited. Alternatively, excitation may occur spontaneously, whereby only a luminescence detector may be present in the particle sensing means 402. The temperature control means 404 for controlling the temperature typically comprises a cooling means for cooling the detection system 400. Such a cooling means may be integrated into the main body of the detection system 400, e.g. biosensor or biochip, or may be external to the main body of the detection system 400. An integrated cooling means may be integrated in, if present, a thin film stack of the detection system 400. Such a cooling means may be a passive cooling means or an active cooling means. The passive cooling means may be an increased thermal capacitance of the detection system 400, such as e.g. introducing a material with high thermal capacitance, e.g. additional mass such as for example a metal body, in the detection system 400, e.g. by providing a material with high thermal capacitance, e.g. additional mass such as for example a metal body, in the packaging of the detection system 400. An alternative or additional passive cooling means may be the use of a heat sink. Such a heat sink may be positioned in the detection system, adjacent thereto or at a distance thereof, whereby the thermal conductivity between the sensing means 402 and the heat sink is high, preferably maximized to enable optimal energy transfer, which can be accomplished by good thermal coupling between the particle sensing means 402 and the heat sink. The latter can e.g. be obtained by clamping and by applying additional conductive paste. For a detection system comprising a reader device and a disposable cartridge adapted for being positioned in the reader, the heat sink may be implemented in the reader device and the disposable cartridge may be thermally coupled to the reader device such that there is a good thermal contact with the heat sink.

Additionally or alternatively the cooling means also may be an active cooling device. Such an active cooling device may be integrated or may be external to the main body of the detection system. In e.g. a detection system comprising a re-usable reader device and a disposable cartridge, the active cooling device preferably is part of the re-usable reader device, although the invention is not limited thereto. The cooling device may be e.g. a Peltier element. Alternative cooling devices may be micro-electro-mechanical refrigeration systems. One example of such a system may be a refrigeration system based on a magnetic refrigeration cycle whereby a micro-electro-mechanical switch, a micro relay, a reed switch or a gate switch is used for switching between an absorption phase and a heat rejection phase of such a cycle. Such devices are described in more detail in e.g. U.S. Pat. No. 6,588,215 B1 from International Business Machines Corporation. Another example of such a system may be a thermoacoustic refrigerator based on providing a temperature difference across a stack using a piezoelectric driver. Thereby a high frequency sound is generated which, by interaction with one or more parts of the stack creates a temperature gradient, thus allowing cooling, as e.g. described in more detail in U.S. Pat. No. 6,804,967 B2 by University of Utah. Still another example of such a system may be a micro-electro-mechanical system whereby expansion of gas is controlled using a micro-electro-mechanical valve, as described in more detail in U.S. Pat. No. 6,804,967 by Technology Applications, Inc. It is an advantage of several of these cooling means that they can be applied using micro-electro-mechanical technology, lithography or thin film deposition techniques such that integration in the detection system can be performed and that their size is compact. By way of illustration, FIG. 7 illustrates an example detection system using a Peltier element as cooling means. The Peltier element also may be used as heating means, as will be described further. The detection system 500 comprises a sensing means 502 adjacent a sample volume 504 for detecting bioactive particles in a sample (not shown), a heating conducting means 506 for providing a thermal contact between the sensing means 502 and the Peltier element 508. Typically, a connector 510, such as e.g. a flexible connector, may be present for powering the different components of the detection system 500.

The temperature control means 404 furthermore may comprise a means for heating. The latter may be the same as the cooling means, such as e.g. in the case of a Peltier element which can be used both for heating and cooling of the detection system or it may be other means such as electric heaters, thermoelectric heaters, resistive heaters, capacitively coupled RF heaters, fluidic circuit heaters, heatpipes, chemical heaters or other types, e.g. heating means based on radiative heating. In the current detection system designs, typically or often available resistive heat sources comprise the wires for magnetic field generation and the magneto-resistive sensor itself. Alternatively a Joule heater can also be applied. The latter may be advantageous if the concentration measuring and temperature stabilization functionality preferably are strictly separated. By way of illustration the example of a Joule heater will now be described in more detail. For a Joule heater, the power dissipation in a conductive strip is proportional to the strip resistance. The latter can be seen from equation [9]

P=I²R [9]

whereby P is the power dissipation, typically dissipated as heat, I is the current and R is the resistance. The specific resistivity of the heater is a function of its temperature,

ρ=ρ₀(1+α(T−T₀)) [10]

where ρ₀ equals the specific resistivity at some reference temperature Tₒ and α is the temperature coefficient of resistance. A typical element used as a Joule heater may be a serpentine implementation, as shown in FIG. 8a. A typical detection system comprising such a resistive heater, such as e.g. a bio-chip having a CMOS stack for front-end signal processing is shown in FIG. 8b. The resistive heater 404 thereby is implemented in a CMOS substrate 602 using CMOS technology directly underneath the particle sensing means 402. The particle sensing means 402 in the present example is a magneto-resistive sensor, whereby a current wire 604 is provided for generating a magnetic field, such that magnetic labels can be detected. The particle sensing means is provided on a detector substrate 606.

The temperature sensing means 406 may be any suitable means for sensing the temperature of the detection system and/or the environment thereof such as e.g. the sample to be measured. For the purpose of temperature stabilization of the detection, a measure of the detection system, especially of the sensing part of the detection system, preferably is performed close to the sample volume. The temperature sensing means 406 may be any temperature sensing means such as thermocouples and other temperature sensing devices. The temperature sensing means 406 also may be based on determining a particular characteristic of the detection system 400. If e.g. a magneto-resistive sensor is used for detection of bioactive particles, an electrical characteristic of the magneto-resistive sensor may be used for determining the temperature. As the sensor resistance is a linear function of temperature, in absence of bioactive particles to be detected or for a known amount of bioactive particles to be detected, the resistance of the sensor may be kept constant to stabilize the temperature. Furthermore, from the resistance value, the temperature could also implicitly or explicitly determined. The latter may be performed at a frequency other than the cross-component that results e.g. from the modulation of the sense current by an external magnetic field, as described in more detail in the first and second aspect of the present invention. In other words, the same features and advantages as described in the first and second aspect of the present invention may be used. Alternatively also the thermal noise power generated by the magneto-resistive sensor may be used as measure of the temperature. The latter can be derived from the following equation [11]

P_{N}=4kTRB [11]

whereby k equals the Boltzmann's constant and B is the measurement bandwidth. The properties as described above also may be measured for a separate electrical component, e.g. resistance or magneto-resistive element, not being used for detection of bioactive particles. As a further alternative, a PN-junction integrated in the detection system may be used, e.g. if applicable in a thin-film stack of the biochip, using equation [12]

$${I}_{D} = {I}_{S} ( {e}^{\frac{{qV}_{D}}{nkT}} - 1 ) \qquad [ 12 ]$$

with I_{D} and V_{D} the junction current and the voltage, n the emission coefficient and I_{S} the saturation current.

The controller 408 for controlling the temperature control means 404 in view of the results provided by the temperature sensing means 406, may be any suitable type of controller. Such a controller may include a computing device, e.g. microprocessor, for instance it may be a micro-controller. In particular, it may include a programmable controller, for instance a programmable digital logic device such as a Programmable Array Logic (PAL), a Programmable Logic Array, a Programmable Gate Array, especially a Field Programmable Gate Array (FPGA). The use of an FPGA allows subsequent programming of the temperature control means, e.g. by downloading the required settings of the FPGA. It may also comprise a memory for storing control signals to be executed by the system and/or reading and/or writing capacities for reading/writing information relating to these control signals. The controller preferably is an on board controller, or in other words preferably is integrated in the detection system such that a compact detection system may be obtained. The controller 408 may be adapted for receiving input signals comprising information about a temperature related parameter and it may be adapted for outputting output signals for the temperature control means, in order to heat or cool or not. The controller 408 may be adapted to control the temperature of the detection system 400, e.g. of the particle sensing means 402 based on feedback information. The controller 408 therefore may be provided in a feedback scheme. By way of example, the invention not limited thereto, two possibilities for incorporating the controller 408 in a feedback scheme are provided. A first example is based on the use of a temperature control means 404 such as e.g. the Peltier element as shown in FIG. 7. The latter is illustrated in FIG. 9, showing a controller 408, a temperature control means 404, e.g. a Peltier element, the particle sensing means 402 and the temperature sensing means 406. A temperature related parameter p(T) is extracted by the temperature sensing means 406 from the particle sensing means 402 or its environment and is combined with predefined optimal temperature information p(T₀) as input for the controller 408. Based on the input information, the controller provides a control signal, e.g. a control current, for the temperature control means 404, thus resulting in heating, cooling or non-operation of the temperature control means 404.

A second example is based on the use of a temperature control means 404 being a Joule heater whereby furthermore the Joule heater is also part of the temperature sensing means 406. As for a Joule heater, the temperature coefficient of resistance is a known material constant, the resistance R can be used as a measure of the temperature T. A possible scheme is shown in FIG. 10. It can be seen that the voltage V across the heater controls the dissipated power P and that the current flowing I through the strip is measured and used for temperature sensing.

In case of an integrated heat source, the temperature profile will not be uniform over the chip volume. However, in a first order approximation, the average sample temperature can be considered linearly related to the power dissipated in the heat source. This relationship is a function of the material properties and geometrical configuration and can be measured beforehand. The transfer of thermal energy to the sample can then be modeled as a constant attenuation factor.

It is an advantage of embodiments according to the third aspect of the present invention that by providing a temperature control means, applied either externally or integrated into the biochip, the temperature of a sample can be optimized. E.g. the temperature of a bodily fluid sample can be maintained at the human body temperature, such that the immunoassay incubation speed is optimized.

It thus is an advantage of embodiments according to the third aspect of the present invention that a reduction of variations in the chemical binding reaction rate and in the electrical sensitivity of the biosensor due to temperature fluctuations can be obtained.

It is an advantage of embodiments of the present invention that a biosensor is obtained that is insensitive to temperature fluctuations. Such temperature-robustness typically is important for point-of-care applications.

Other arrangements for accomplishing the objectives of the detection methods and systems embodying the invention will be obvious for those skilled in the art. It is to be understood that although preferred embodiments, specific constructions and configurations, as well as materials, have been discussed herein for devices according to the present invention, various changes or modifications in form and detail may be made without departing from the scope and spirit of this invention. For example, whereas the third aspect of the present invention has been described with reference to a detection system, the present invention also relates to a method for detecting bioactive particles. Such a method typically comprises the step of determining whether a temperature related parameter indicates that an actual temperature of a particle sensing means is above a predetermined temperature, cooling the particle sensing means until substantially the predetermined temperature is reached, determining a qualitative or quantitative characteristic of bioactive particles using said temperature-controlled particle sensing means.

1. A detection system (100, 150) for qualitative or quantitative detection of a magnetic field property of a modulated magnetic field, the detection system (100, 150) comprising at least one magnetic sensor element (102), a current controller (104) for providing a sensing current (Iₛₑₙₛₑ) with a first frequency f₁ flowing through said at least one magnetic sensor element (102) and a controlling means (108),
wherein said controlling means (108) is adapted for obtaining an electric characteristic from said at least one magnetic sensor element (102) at a first frequency f₁ for deriving a temperature-related parameter of said at least one magnetic sensor and
said controlling means (108) furthermore is adapted for obtaining an electric characteristic from said magnetic sensor element (102) at least a second frequency (f₂), said at least a second frequency (f₂) being different from said first frequency (f₁), for deriving a qualitative or quantitative characteristic of said magnetic field property taking into account said derived temperature-related parameter.

2. A detection system (100, 150) according to claim 1, wherein the magnetic field property is the magnitude of a magnetic field generated by an adjacent electrical current (I_{adj}) or magnetic particles.

3. A detection system (100, 150) according to claim 1, said magnetic field property having a characteristic magnetic field frequency (fₘ), wherein said first frequency (f₁) is a frequency substantially different from said magnetic field frequency (fₘ) and said at least a second frequency (f₂) is at least one of a sum or difference of said magnetic field frequency fₘ and said first frequency (fₘ+f₁,fₘ−f₁).

4. A detection system (100) according to claim 3, said detection system (100) furthermore comprising a modulating means (112) for modulating said magnetic field property at said magnetic field frequency (fₘ).

5. A detection system (100) according to claim 3, wherein said first frequency (f₁) equals 0 hertz.

6. A detection system (100, 150) according to claim 1, wherein said controlling means (108) is adapted for obtaining an electric characteristic from said magnetic sensor element (102) at a first frequency f₁ and said obtaining an electric characteristic from said magnetic sensor element (102) at a second frequency f₂ is performed at the same time.

7. A detection system (100, 150) according to claim 1, wherein said at least one magnetic sensor element (102) is at least one magneto-resistive sensor element.

8. A detection system (100, 150) according to claim 7, wherein said at least one magneto resistive sensor element (102) is any of a giant magneto-resistive sensor element, an anisotropic magneto-resistive sensor element or a tunnel magneto-resistive sensor element.

9. A method (200) for qualitatively and quantitatively detection of a magnetic field property of a modulated magnetic field, the method comprising
providing a sensing current (Iₛₑₙₛₑ) flowing through at least one magnetic sensor (102) at a first frequency (f₁),
deriving (204, 206) at said first frequency (f₁) a temperature-related parameter of said at least one magnetic sensor (102),
deriving (210, 212) at a second frequency (f₂) a qualitative or quantitative characteristic of said magnetic field property using said at least one magnetic sensor (102), taking into account a temperature-related parameter of said at least one magnetic sensor (102).

10. A method according to claim 9, wherein said deriving (204, 206) a temperature-related parameter comprises obtaining (206) an electrical characteristic (E₁) of said at least one magnetic sensor (102) at the first frequency (f₁) and determining said temperature-related parameter based on said first electrical characteristic (E₁) or a component thereof.

11. A method according to claim 10, wherein said deriving a qualitative or quantitative characteristic comprises obtaining (210) a second electrical characteristic (E₂) of said at least one magnetic sensor (102) at the second frequency (f₂) and determining (212) said qualitative or quantitative characteristic based on said second electrical characteristic (E₂) and said temperature-related parameter.

12. Use of a detection system (100, 150) for qualitative or quantitative detection of a magnetic field property of a modulated magnetic field for molecular diagnostics, biological sample analysis, or chemical sample analysis,
the detection system (100, 150) comprising at least one magnetic sensor element (102), a current controller (104) for providing a sensing current (Iₛₑₙₛₑ) with a first frequency (f₁) flowing through said at least one magnetic sensor element (102) and a controlling means (108),
wherein said controlling means (108) is adapted for obtaining an electric characteristic from said magnetic sensor element (102) at a first frequency f₁ for deriving a temperature-related parameter of said at least one magnetic sensor element and
said controlling means (108) furthermore is adapted for obtaining an electric characteristic from said at least one magnetic sensor element (102) at least a second frequency (f₂), said at least a second frequency (f₂) being different from said first frequency (f₁), for deriving a magnetic field property, taking into account said derived temperature-related parameter.
